(19) United States
(12) Patent Application Publication
(10) Pub. No.: US 2006/0068532 A1
(43) Pub. Date: Mar. 30, 2006

(54) Dual-gate thin-film transistor

(75) Inventors: Paul J. Schuele, Washougal, WA (US); Apostolos T. Voutsas, Vancouver, WA (US)

Correspondence Address: SHARP LABORATORIES OF AMERICA, INC, 5750 NW PACIFIC RIM BLVD, CAMAS, WA, 98642, US

(73) Assignee: Sharp Laboratories of America, Inc.

(21) Appl. No.: 10/953,913

(22) Filed: Sep. 28, 2004

(51) Int. Cl. H01L 21/84

(52) U.S. Cl. 438/149; 438/479

(57) ABSTRACT

A dual-gate thin film transistor (DG-TFT) and associated fabrication method are provided. The method comprises: forming a first (back) gate in a first horizontal plane; forming source/drain (S/D) regions and an intervening channel region in a second horizontal plane, overlying the first plane; and, forming a second (top) gate in a third horizontal plane, overlying the second plane. The S/D regions and intervening channel region have a combined length, smaller than the length of the first gate. A substrate insulating layer is formed over the substrate, made from a material such as SiO2. A first gate insulation layer is formed over the first gate. Amorphous silicon (a-Si) is deposited over the first gate insulation layer and crystallized. The S/D and channel regions are formed from the crystallized Si layer. A second gate oxide layer is formed over the channel region.

### BACKGROUND OF THE INVENTION

1. Field of the Invention

This invention generally relates to integrated circuit (IC) and liquid crystal display (LCD) fabrication and, more particularly, to a dual-gate thin-film transistor DG-TFT, with the source, drain, and intervening channel regions for a top gate, directly overlying a bottom gate.

2. Description of the Related Art

There are several fabrication processes that can be manipulated to influence the characteristics of a transistor. One of the most important transistor properties is threshold voltage or Vt, which is a measure of the field at which a device begins to conduct. Vt affects the speed and power consumption of CMOS devices with higher speed and higher power at lower Vt and low speed/power for high Vt. Thus, it is useful to be able to vary the Vt of a transistor for programmable power circuits, and it is useful to tune Vt to compensate for variations in the fabrication process. Typically, Vt is a set property that is established during fabrication as a result of doping and device geometries.

FIG. 1 depicts a cross-sectional view of a conventional dual-gate transistor (prior art). It is desirable that Vt be made user controllable, depending on the ultimate function of the transistor. One method of controlling TFT Vt is by adding a second gate electrode under the TFT gate electrode, so a second field can be applied to the channel by biasing the bottom gate. The second gate permits a TFT Vt to be adjustable in accordance to use, and allows a user to compensate for manufacturing tolerances. Conventional dual-gate TFTs are fabricated with the bottom gate edges inside the source/drain contacts and complex processes have been reported to produce self-aligned dual gate structures. The conventional DG-TFT is formed with top and bottom gates of approximately the same size. If the top gate overlaps the edges of the bottom gate, the TFT channel length varies due to changes in the bottom gate edge profile. If the bottom gate is larger than the top gate and has vertical sidewalls, then undoped regions are formed in the active channel adjacent the back gate sides, which are undesirable because conduction in these regions is not controlled by the voltage applied to the top gate and the TFT drive current will be decreased by high resistance in these regions. In both cases TFT performance is affected by differences in alignment between the edge of the top gate and the edge of the bottom gate.

It would be advantageous if the undoped regions formed at the edge of a bottom gate could be moved outside the active channel, so that the parasitic effects would not affect the performance of the DG TFT.

It would be advantageous if the top and bottom gate edges could be laterally separated, reducing device sensitivity to misalignment between the two overlaying layers.

### SUMMARY OF THE INVENTION

The present invention describes the fabrication of a dual-gate TFT having two controlling “gates”, a top gate and a back (bottom) gate. One unique feature of this device is the extension of the bottom gate beyond the contacts to the S/D electrodes of the device, to alleviate parasitic effects emanating from the co-integration of this device with other device types. One application of this device is in Vth control circuits, although other applications, such as co-integration of low-voltage (low Vt) and high-speed devices (high Isat) can also be realized.

The invention can be termed a planar back-gate structure, which is biased in order to change the performance of a conventional planar TFT fabricated over the back gate electrode. This structure prevents the formation of the undoped regions by extending the bottom gate under the contacts to the TFT source/drain regions. Accordingly, a method is provided for forming a dual-gate thin film transistor, the method comprises: forming a first (back or bottom) gate in a first horizontal plane; forming source/drain (S/D) regions and an intervening channel region in a second horizontal plane, overlying the first plane; and, forming a second (top) gate in a third horizontal plane, overlying the second plane. The S/D regions overlie the first gate, between the first gate vertical sides. Alternately stated, the S/D regions and intervening channel region have a combined length, smaller than the length of the first gate.

More specifically, a substrate is provided made from a material such as Si, quartz, glass, or plastic. A substrate insulating (bottom isolation oxide) layer is formed over the substrate, made from a material such as SiO2. The first gate is formed by depositing polysilicon overlying the substrate insulation layer, doping the polysilicon, annealing, and, patterning the polysilicon. Alternately, the first and second gates can be a metal material. A first gate insulation layer is formed over the first gate. Amorphous silicon (a-Si) is deposited over the first gate insulation layer and crystallized. The S/D and channel regions are formed from the crystallized Si layer. A second gate oxide layer is formed over the channel region. Again, the second gate can be doped polysilicon or a metal.

Additional details of the above-described method, and a dual gate TFT are presented below.

### BRIEF DESCRIPTION OF THE DRAWINGS

FIG. 1 depicts a cross-sectional view of a conventional dual-gate transistor (prior art).

FIG. 2 is a partial cross-sectional view of the present invention dual-gate thin film transistor (DG-TFT).

FIG. 3 is a partial cross-sectional view of a DG-TFT structure with simulated doping levels.

FIG. 4 is a graph illustrating drain current (Id) with respect to top gate voltage (Vg), at different back gate voltages (Vbg).

FIG. 5 is a graph showing the effects on saturation current (with Id at Vg=6V), of different back gate voltages.

FIG. 6 is a graph depicting off current (with Id at Vg=0V), at different back gate voltages.

FIG. 7 is a graph depicting curves of saturation current versus off current (power consumption) at different back gate dopings.

FIG. 8 is a flowchart illustrating the present invention method for forming a dual-gate thin film transistor (DG-TFT).

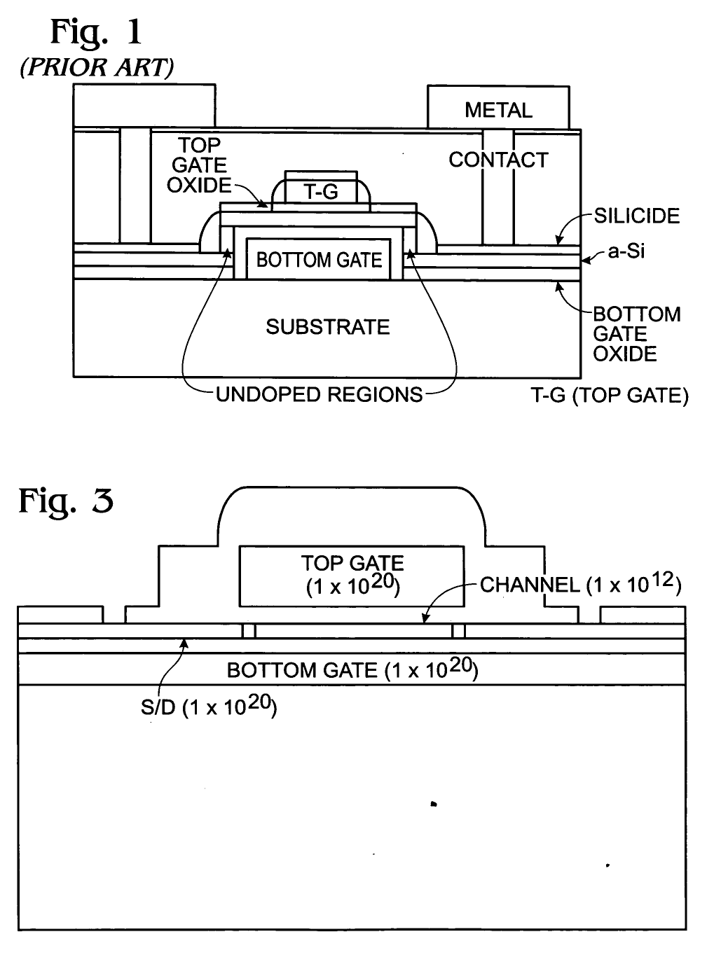

### DETAILED DESCRIPTION OF THE PREFERRED EMBODIMENTS

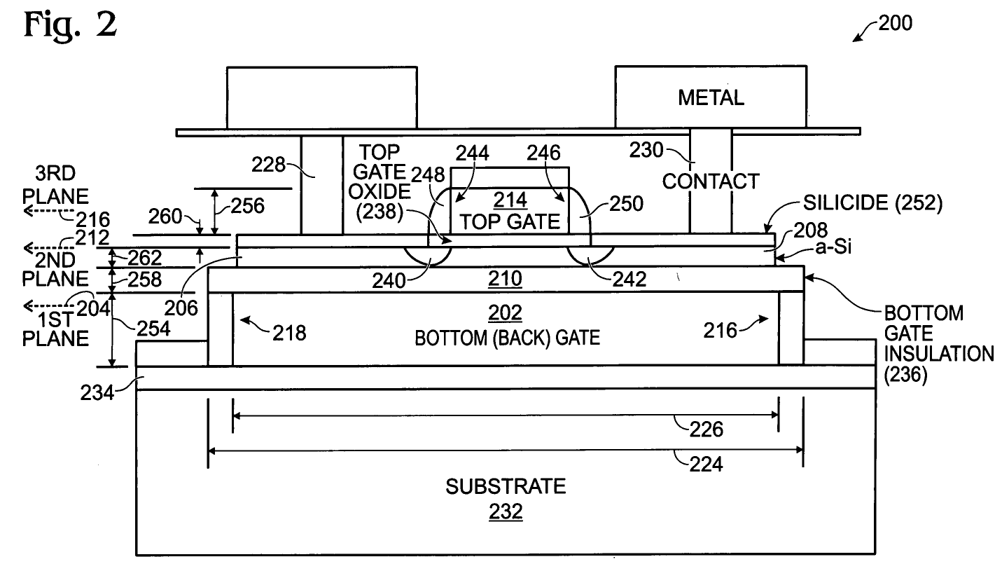

FIG. 2 is a partial cross-sectional view of the present invention dual-gate thin film transistor (DG-TFT). The DG-TFT 200 comprises a first (back) gate 202 aligned in a first horizontal plane 204. A first polycrystalline silicon (poly-Si) source/drain (S/D) region 206, a second poly-Si S/D region 208, and an intervening poly-Si channel region 210 are aligned in a second horizontal plane 212, overlying the first plane 204. A second gate 214 is aligned in a third horizontal plane 216, overlying the second plane 212.

The definition of the element's respective horizontal planes is somewhat arbitrary. The element positions can be defined with respect to a top surface, bottom surface, or by approximate mid-height. As shown, the elements 202, 206, 208, 210, and 212 are defined as their mid-heights being in a specified plane. However, their positions can alternately be defined by top or bottom surfaces. Note, the term “horizontal” is used herein as a convenient visual reference. The planes need not actually be horizontal.

Alternately, the DG transistor 200 can be considered to have two, instead of three horizontal planes. A bottom surface of the first gate 202 is aligned in one horizontal plane. The top surfaces of the S/D regions 206/208 and channel 210, and a bottom surface of the second gate 214 are aligned approximately in a second horizontal plane. In accordance with this definition, a conventional “planar” transistor has the top surfaces of the S/D and channels regions, and the bottom surface of an overlying gate all in a single plane.

The first gate 202 has vertical sides 216 and 218. Insulating sidewalls 220 and 222 are shown over the first gate vertical sides 216/218, respectively. The first and second S/D regions 206 and 208 overlie the first gate 202, between the first gate vertical sides 216 and 218. The first gate 202 has a first gate length 224. The first S/D region 206, second S/D region 208, and intervening channel region 210 have a combined second length 226, smaller (shorter) than the first length 224.

Interlevel interconnects 228 and 230 are formed to the first and second S/D regions 206 and 208, respectively, overlying the first and second S/D regions 206 and 208. Thus, the interconnects 228 and 230 are also between (within the vertical boundaries formed by) the first gate sides 216 and 218.

Also shown is a substrate 232 made from a material such as Si, quartz, glass, or plastic. A substrate insulating (bottom isolation oxide) layer 234 overlies the substrate 232, and is made from a material such as SiO2, SiO2/Si3N4/SiO2, or organic insulators such as polyimide. However, the DG-TFT 200 is not limited to any particular substrate or substrate insulator material. The first gate 202 is formed overlying the substrate insulation layer 234.

A first (bottom) gate insulation layer 236 overlies the first gate 202. The first S/D region 206, second S/D region 208, and channel region 210 are formed over the first gate insulation layer 236. A second (top) gate oxide layer 238 overlies the channel region 210, and the second gate 214 is formed overlying the second gate insulation layer 238. The second gate oxide layer 238 can be made from the same list of materials as the substrate insulation layer 234, mentioned above.

In one aspect, lightly doped drain (LDD) areas 240 and 242 are formed in the first and second S/D regions 206 and 208, respectively. In another aspect, the second gate 214 has vertical sides 244 and 246, with oxide spacers 248 and 250 over the second gate vertical sides 244 and 246, respectively. For example, oxide spacers 248 and 250 may be useful, protecting the second gate 214, if silicide 252 is formed overlying the first and second S/D regions 206 and 208.

In one aspect, the first gate 202 has a thickness 254 in the range of 1000 to 3000 Å and the second gate 214 has a thickness 256 in the range of 1000 to 3000 Å. The first gate insulation layer 236 may have a thickness 258 in the range of 200 to 1000 Å. Likewise, the second gate oxide layer 238 has a thickness 260 in the range of 200 to 1000 Å. The first S/D region 206, second S/D region 208, and intervening channel region 210 may have a thickness 262 in the range of 300 to 1500 Å. However, the DG-TFT 200 is not necessarily limited to just the above-mentioned thicknesses.

### Functional Description

The DG-TFT can be fabricated using the following exemplary process sequence:

Providing an insulating substrate, which may be quartz, glass, or plastic;

Deposit an isolation oxide layer, which protects TFT devices from substrate impurities;

Deposit 1000 to 3000 Å poly-Si for the first gate electrode. The poly-Si may be in-situ doped, or doped by ion implantation;

Pattern and etch the first gate electrode such that the edge of the gate is outside the position of contacts to source/drain regions;

Deposit bottom isolation (substrate insulation layer) oxide, between 200 and 1000 Å thick;

Deposit active Si 300 to 1000 Å thick.

Laser crystallize the a-Si;

Deposit second (top) gate oxide 200 to 1000 Å thick;

Deposit top gate poly silicon 1000 to 2000 Å thick;

Pattern second gate poly-Si with photolithography and dry etch;

Optionally ion implant LDD regions;

Optionally form oxide spacer;

Ion implant second gate and S/D regions;

Activation anneal;

Optionally form silicide on S/D regions and second gate;

Continue with conventional isolation and metal interconnect fabrication.

FIG. 3 is a partial cross-sectional view of a DG-TFT structure with simulated doping levels. The effects of different back-gate conditions on an NMOS TFT have been simulated using a 2-micron (um) top gate electrode to illustrate some applications of the invention. The doping densities, per cubic centimeter, of the gates, channel, and source/drain regions are shown.

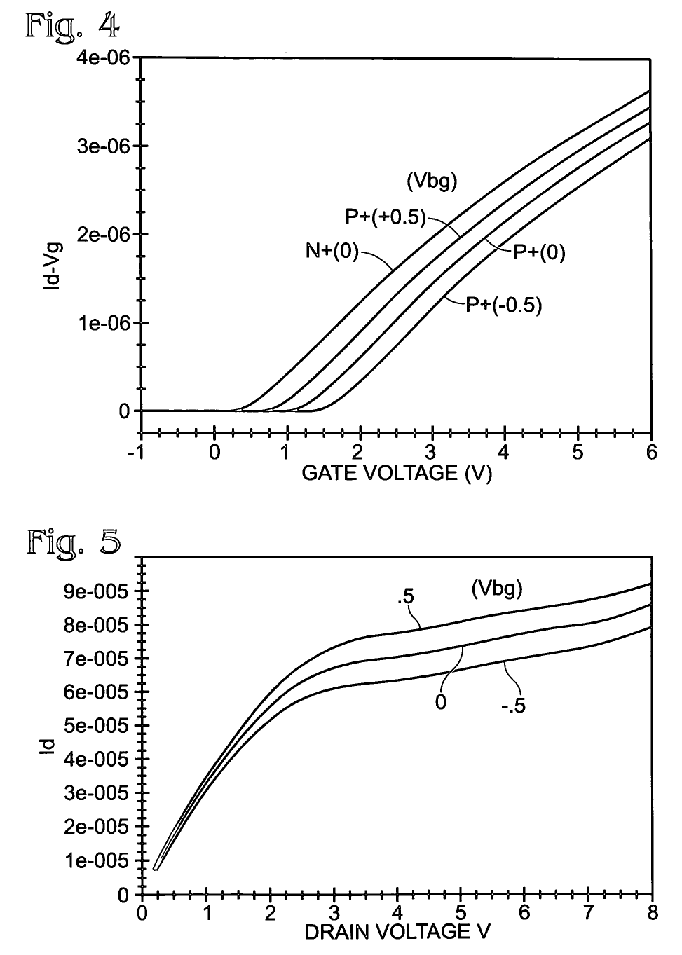

FIG. 4 is a graph illustrating drain current (Id) with respect to top gate voltage (Vg), at different back gate voltages (Vbg). Simulations show that it is possible to change the performance of a planar NMOS TFT by adjusting the bias on the first (back) gate. FIG. 4 shows the effect of back gate voltage on the TFT device Vt, with a back gate voltage of −0.5V shifting Vt upwards by 390 mV. A similar effect can be obtained by doping the back gate P+ instead of N+. In this case, the N channel transistor Vt is shifted higher with a corresponding decrease in Isat and Ioff. The Vt shifts are shown in FIG. 4.

FIG. 5 is a graph showing the effects on saturation current (with Id at Vg=6V), of different back gate voltages.

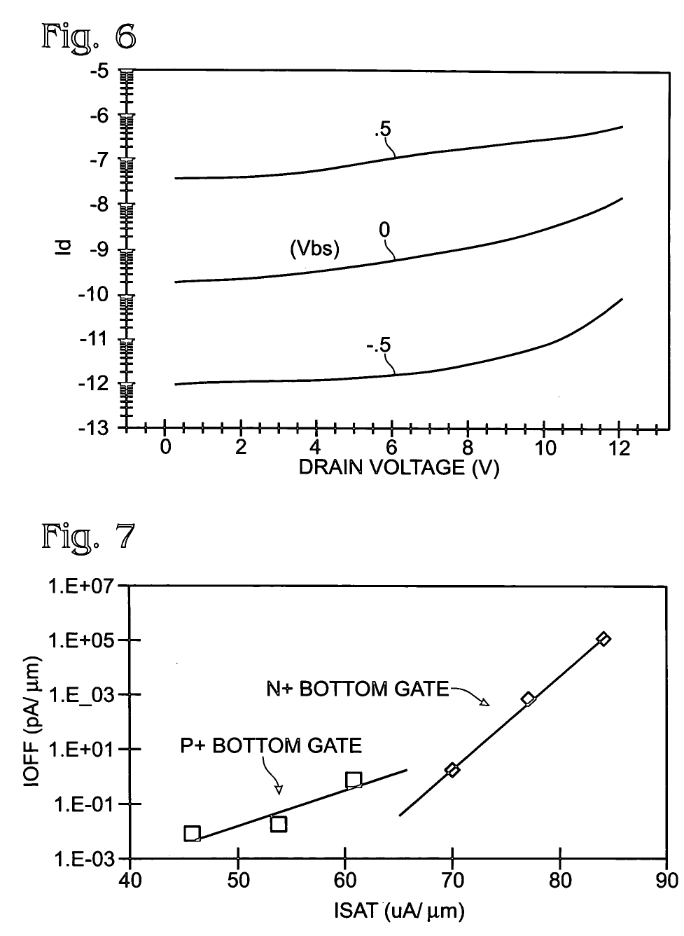

FIG. 6 is a graph depicting off current (with Id at Vg=0V), at different back gate voltages. With the back gate bias at −0.5V, Isat decreases by about 10% and Ioff decreases by more than two orders of magnitude. A back gate voltage of +0.5V has the opposite effect. Thus, a product can set a high-speed mode (low Vt, high Isat) with higher power consumption by setting the back gate to 0.5V. By adjusting the back gate voltage to −0.5V the product can be set for a slower low power mode.

Table 1 summarizes the effects of back gate doping and bias on the performance of L=2 micron TFT's.

TABLE 1
Simulated NMOS TFT performance versus back gate voltage
for L = 2 μm.

| | Vbg | Vt | Isat | Ioff |
|---|---|---|---|---|
| BG doping | Volt | Volt | uA/um | pA/um |
| N+ | 0.5 | 0.11 | 84 | 100000 |
| N+ | 0 | 0.5 | 77 | 580 |
| N+ | −0.5 | 0.85 | 70 | 1.5 |
| P+ | 0.5 | 0.91 | 61 | 0.65 |
| P+ | 0 | 1.25 | 54 | 0.015 |
| P+ | −0.5 | 1.61 | 46 | 0.007 |

FIG. 7 is a graph depicting curves of saturation current versus off current (power consumption) at different back gate dopings. A striking improvement in the off current can be observed. In summary, it is possible to produce significant changes in TFT performance by adjusting the bias and doping of a back gate. There are several possible product applications of this effect. Some examples are:

Adjusting TFT Vt by changing back gate bias based on feedback from a voltage controlled oscillator. This technique allows active control of transistor Vt to compensate for process variations;

Multiple operating modes with different trade-offs between speed and power consumption controlled by back gate bias;

Simultaneous production of high-speed and low-power transistors with the same TFT process flow by adding a back gate under the low-power transistors. This flow requires only one additional mask to pattern the back gate electrode.

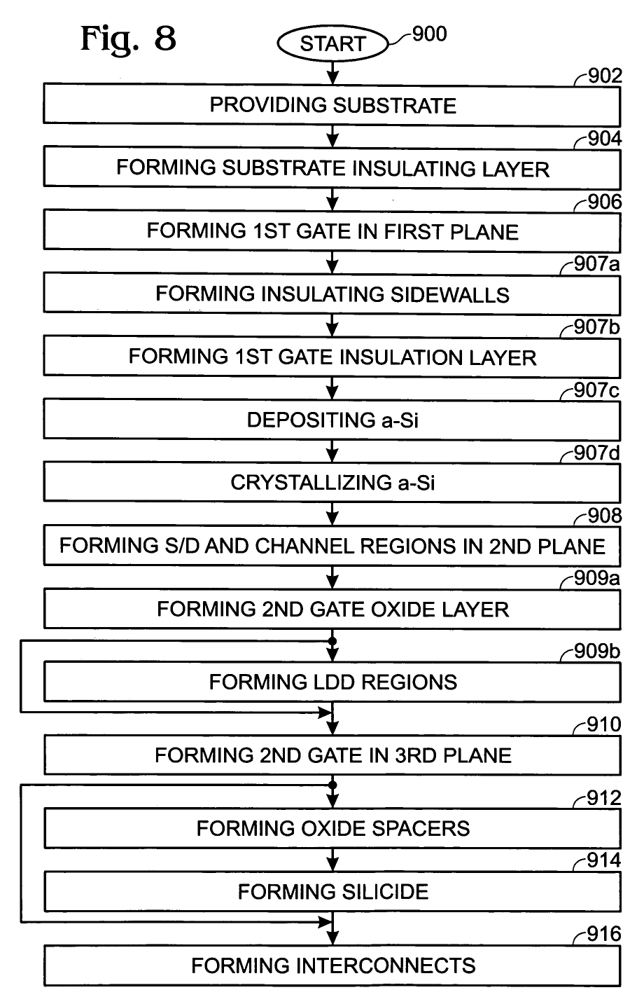

FIG. 8 is a flowchart illustrating the present invention method for forming a dual-gate thin film transistor (DG-TFT). Although the method is depicted as a sequence of numbered steps for clarity, no order should be inferred from the numbering unless explicitly stated. It should be understood that some of these steps may be skipped, performed in parallel, or performed without the requirement of maintaining a strict order of sequence. The method starts at Step 900.

Step 902 provides a substrate made from a material such as Si, quartz, glass, or plastic. Step 904 forms a substrate insulating (bottom isolation oxide) layer overlying the substrate, made from a material such as SiO2, SiO2/Si3N4/SiO2, or organic insulators such as polyimide. Step 906 forms a first (back) gate in a first horizontal plane. Step 908 forms a first source/drain (S/D) region, a second S/D region, and an intervening channel region in a second horizontal plane, overlying the first plane. Step 910 forms a second (top) gate in a third horizontal plane, overlying the second plane. Step 916 forms interlevel interconnects to the first and second S/D regions, overlying the first and second S/D regions.

In one aspect, Step 906 forms a first gate with vertical sides. An additional step, Step 907a, forms insulating sidewalls over the first gate vertical sides. Then, forming the first and second S/D regions in Step 908 additionally includes forming the first and second S/D regions overlying the first gate, between the first gate vertical sides. In a different aspect Step 906 forms the first gate with a first gate length. Then, Step 908 forms the first S/D region, second S/D region, and intervening channel region with a combined second length, smaller than the first length.

In one aspect, forming the first gate in Step 906 includes the sub-steps (not shown) of: depositing polysilicon overlying the substrate insulation layer to a thickness of 1000 to 3000 Å; doping the polysilicon; annealing; and, patterning the polysilicon. Alternately, the first gate can be a conventional metal material.

In a different aspect, Step 907b forms a first gate insulation layer overlying the first gate having a thickness of 200 to 1000 Å. Step 907c conformally deposits an amorphous silicon (a-Si) layer, having a thickness in the range of 300 to 1500 Å, overlying the first gate insulation layer. Step 907d crystallizes the a-Si, through laser, furnace, rapid thermal annealing, or any other conventional method, depending on the heat sensitivity of the substrate material. Then, Step 908 forms the first S/D, second S/D, and channel regions from the conformally deposited amorphous Si layer.

In one aspect, Step 909a forms a second gate oxide layer overlying the channel region having a thickness of 200 to 1000 Å. The second gate oxide layer can be made from the same materials as the substrate insulation layer, mentioned above. Then, forming the second gate in Step 910 includes the sub-steps (not shown) of: depositing polysilicon overlying the second gate insulation layer to a thickness of 1000 to 3000 Å; patterning the polysilicon; doping the polysilicon; and, annealing. However, the second gate can be made from other conventional materials.

In a different aspect, Step 909b, prior to doping the polysilicon, optionally forms lightly doped drain (LDD) areas in the first and second S/D regions. Typically, the step of doping the second gate polysilicon, mentioned above as a sub-step of Step 910, additionally includes simultaneously doping the first and second S/D regions.

In one aspect, forming the second gate in Step 910 includes forming the second gate with vertical sides. Then, Step 912 optionally forms oxide spacers over the second gate sidewalls, and Step 914 optionally forms silicide overlying the first and second S/D regions.

A DG-TFT device and associated fabrication process have been presented. Various process specifics have been described to clarify the invention. However, the invention is not limited to just these examples. Likewise, specific materials have been mentioned. However, the invention can be enabled using a almost any conventional TFT material. Other variations and embodiments of the invention will occur to those skilled in the art.

We claim:

1. A method for forming a dual-gate thin film transistor (DG-TFT), the method comprising:
forming a first gate in a first horizontal plane;
forming a first source/drain (S/D) region, a second S/D region, and an intervening channel region in a second horizontal plane, overlying the first plane; and,
forming a second gate in a third horizontal plane, overlying the second plane.

2. The method of claim 1 wherein forming the first gate further includes forming a first gate with vertical sides;
the method further comprising:
forming insulating sidewalls over the first gate vertical sides; and,
wherein forming the first and second S/D regions additionally includes forming the first and second S/D regions overlying the first gate, between the first gate vertical sides.

3. The method of claim 1 wherein forming the first gate in the first horizontal plane includes forming the first gate with a first gate length; and,
wherein forming the first S/D region, second S/D region, and intervening channel region includes forming the first S/D region, second S/D region, and intervening channel region with a combined second length, smaller than the first length.

4. The method of claim 3 further comprising:
forming interlevel interconnects to the first and second S/D regions, overlying the first and second S/D regions.

5. The method of claim 2 further comprising:
providing a substrate made from a material selected from group including Si, quartz, glass, and plastic;
forming a substrate insulating layer overlying the substrate, made from a material selected from the group including SiO2, SiO2/Si3N4/SiO2, and organic insulators such as polyimide; and,
wherein forming the first gate includes:
depositing polysilicon overlying the substrate insulation layer;
doping the polysilicon;
annealing; and,
patterning the polysilicon.

6. The method of claim 5 further comprising:
forming a first gate insulation layer overlying the first gate;
conformally depositing an amorphous silicon (a-Si) layer, having a thickness in the range of 300 to 1500 Å, overlying the first gate insulation layer; and,
wherein forming the first S/D, second S/D, and channel regions includes forming the regions from the conformally deposited amorphous Si layer.

7. The method of claim 6 further comprising:
crystallizing the a-Si layer.

8. The method of claim 6 further comprising:
forming a second gate oxide layer overlying the channel region;
wherein forming the second gate includes:
depositing polysilicon overlying the second gate insulation layer;
patterning the polysilicon;
doping the polysilicon; and,
annealing.

9. The method of claim 8 further comprising:
prior to doping the polysilicon, forming lightly doped drain (LDD) areas in the first and second S/D regions; and,
wherein doping the second gate polysilicon includes simultaneously doping the first and second S/D regions.

10. The method of claim 8 wherein forming the second gate includes forming the second gate with vertical sides; and
the method further comprising:
forming oxide spacers over the second gate sidewalls; and,
forming silicide overlying the first and second S/D regions.

11. The method of claim 8 wherein depositing polysilicon overlying the substrate insulation layer includes depositing polysilicon to a thickness in the range of 1000 to 3000 Å; and,
wherein depositing polysilicon overlying the second gate insulation layer includes depositing polysilicon to a thickness in the range of 1000 to 3000 Å.

12. The method of claim 6 wherein forming the first gate insulation layer includes depositing insulator to a thickness in the range of 200 to 1000 Å.

13. The method of claim 8 wherein forming the second gate oxide layer includes depositing insulator to a thickness in the range of 200 to 1000 Å.

14. The method of claim 8 wherein forming the second gate oxide layer includes forming the second gate oxide layer from a material selected from the group including SiO2, SiO2/Si3N4/SiO2, and organic insulators such as polyimide.

15. A dual-gate thin film transistor (DG-TFT) comprising:
a first gate aligned in a first horizontal plane;
a first polycrystalline silicon (poly-Si) source/drain (S/D) region, a second poly-Si S/D region, and an intervening poly-Si channel region aligned in a second horizontal plane, overlying the first plane; and,
a second gate aligned in a third horizontal plane, overlying the second plane.

16. The DG-TFT of claim 15 wherein the first gate has vertical sides; and,
the DG-TFT further comprising:
insulating sidewalls over the first gate vertical sides; and,
wherein the first and second S/D regions overlie the first gate, between the first gate vertical sides.

17. The DG-TFT of claim 15 wherein the first gate has a first gate length; and,
wherein the first S/D region, second S/D region, and intervening channel region have a combined second length, smaller than the first length.

18. The DG-TFT of claim 17 further comprising:
interlevel interconnects to the first and second S/D regions, overlying the first and second S/D regions.

19. The method of claim 16 further comprising:
a substrate made from a material selected from group including Si, quartz, glass, and plastic;
a substrate insulating layer overlying the substrate, made from a material selected from the group including SiO2, SiO2/Si3N4/SiO2, and organic insulators such as polyimide; and,
wherein the first gate is formed overlying the substrate insulation layer.

20. The DG-TFT of claim 19 further comprising:
a first gate insulation layer overlying the first gate; and,
wherein the first S/D, second S/D, and channel regions are formed overlying the first gate insulation layer.

21. The DG-TFT of claim 20 further comprising:
a second gate oxide layer overlying the channel region; and,
wherein the second gate is formed overlying the second gate insulation layer.

22. The DG-TFT of claim 21 further comprising:
lightly doped drain (LDD) areas in the first and second S/D regions.

23. The DG-TFT of claim 21 wherein the second gate has vertical sides;
the DG-TFT further comprising:
oxide spacers over the second gate vertical sides; and,
silicide overlying the first and second S/D regions.

24. The DG-TFT of claim 21 wherein the first gate has a thickness in the range of 1000 to 3000 Å; and,
wherein the second gate has a thickness in the range of 1000 to 3000 Å.

25. The DG-TFT of claim 20 wherein the first gate insulation layer has a thickness in the range of 200 to 1000 Å.

26. The DG-TFT of claim 21 wherein the second gate insulation layer has a thickness in the range of 200 to 1000 Å.

27. The DG-TFT of claim 15 wherein the first S/D region, second S/D region, and intervening channel region have a thickness in the range of 300 to 1500 Å.

28. The DG-TFT of claim 21 wherein the second gate oxide layer is made from a material selected from the group including SiO2, SiO2/Si3N4/SiO2, and organic insulators such as polyimide.
